(19) United States
(12) Patent Application Publication
(10) Pub. No.: US 2025/0389019 A1
(43) Pub. Date: Dec. 25, 2025

(54) APPARATUS FOR SUPPLYING A VAPORIZED REACTANT AND ASSOCIATED REACTOR SYSTEMS AND METHODS

(71) Applicant: ASM IP Holding B.V., Almere (NL)

(72) Inventors: Jonathan Bakke, Phoenix, AZ (US); Paul Ma, Scottsdale, AZ (US); Chad Russell Lunceford, Phoenix, AZ (US); Shuaidi Zhang, Chandler, AZ (US)

(21) Appl. No.: 19/241,626

(22) Filed: Jun. 18, 2025

Related U.S. Application Data
(60) Provisional application No. 63/662,942, filed on Jun. 21, 2024.

(51) Int. Cl. C23C 16/455; C23C 16/448

(52) U.S. Cl. CPC C23C 16/45544; C23C 16/448; C23C 16/45557

(57) ABSTRACT

Apparatus for supplying a vaporized reactant to a reaction chamber are disclosed. The apparatus disclosed includes a process control chamber in fluid communication with a supply vessel and an injection gas source is fluid communication with the process control chamber and configured to enable modification of the pressure within the process control chamber. Reactor systems including the apparatus for supplying a vaporized reactant to a reaction chamber are also disclosure. Methods for supplying vaporized reactant to a reaction are also disclosed.

### CROSS-REFERENCE TO RELATED APPLICATIONS

This application is a nonprovisional of, and claims priority to and the benefit of, U.S. Provisional Patent Application No. 63/662,942, filed Jun. 21, 2024 and entitled “APPARATUS FOR SUPPLYING A VAPORIZED REACTANT AND ASSOCIATED REACTOR SYSTEMS AND METHODS,” which is hereby incorporated by reference herein.

### FIELD

The present disclosure relates generally to the field of semiconductor processing apparatus, associated processing methods, and to the field of device and integrated circuit manufacture. More particularly, the present disclosure generally relates to apparatus for supplying vaporized reactants and reactor systems including such apparatus. In addition, the present disclosure generally relates to methods of forming a vaporized reactant.

### BACKGROUND

During semiconductor processing various reactant vapors may be fed into a reaction chamber. In some applications reactant vapors can be generated from source chemicals that are in the solid phase or the liquid phase (at ambient pressure and temperature). These solid or liquid sources may be heated to produce a vaporized reactant for a reaction process, such as vapor deposition, for example. Chemical Vapor Deposition (CVD) may call for the supply of continuous streams of reactant vapor to the reaction chamber. Atomic Layer Deposition (ALD), pulsed CVD, and hybrids thereof may call for continuous streams or a pulsed supply of reactant vapor to the reaction chamber, depending on the desired configuration, including time-divided and spaced-divided pulsed processes. Reactant vapors from solid or liquid sources can also be useful for other types of chemical reactions employed in the semiconductor industry (e.g., etching, doping, etc.) as well as for a variety of other industries. However, due in part to small process windows between vaporization and decomposition temperatures, low vapor pressure, and the need for uniform dosage, there remains a continuing demand for improved control over vapor phase delivery from a solid or liquid source chemical.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to apparatus for supplying a vaporized reactant to a reaction chamber as well as reactor system including such apparatus. The apparatus can include a process control chamber positioned downstream of and in fluid communication with a source vessel. The process control chamber can be configured to collect (e.g., accumulate) and transfer the vaporized reactant to a reaction chamber downstream of the process control chamber. An injection gas source can be fluidly connected to the process control chamber and configured to supply an injection gas to the process control chamber to enable pressure control within the process control chamber. For example, a measured amount of vaporized reactant can be transferred to the process control chamber and the injection gas can be supplied to the process control chamber to provide a known amount of vaporized reactant at a desired pressure within the process control chamber. Subsequently the controlled amount of vaporized reactant at the desired pressure can be transferred to the reaction chamber.

In one aspect a reactor system is provided comprising: a reaction chamber configured to receive one or more substrates; a source vessel configured to supply a vaporized reactant to the reaction chamber, the source vessel comprising a source inlet, a source outlet, and an interior space adapted for receiving a volume of a source material; a process control chamber disposed between the source vessel and the reaction chamber, the process control chamber being in fluid communication with the source vessel and the reaction chamber and configured to collect a measured amount of the vaporized reactant from the source vessel prior to delivery of the measured amount of the vaporized reactant to the reaction chamber at a predetermined pressure, the injection gas source configured to supply an injection gas to the process control chamber to enable modification of a pressure within the process control chamber.

In some embodiments the reactor system further comprises a pressure transducer configured to monitor the pressure in the process control chamber.

In some embodiments the reactor system further comprises a process control valve disposed between the injection gas source and the process control chamber and configured for controlling the supply of the injection gas to the process control chamber.

In some embodiments the reactor system further comprises a control system configured to communicate with at least the pressure transducer and the process control valve to enable a controlled delivery of the vaporized reactant at a desired pressure to the reaction chamber from the process control chamber.

In some embodiments the injection gas source is configured to increase a pressure within the process control chamber above a pressure within the reaction chamber.

In some embodiments the injection gas source is fluidly coupled directly to the process control chamber.

In some embodiments the reactor system further comprises a flow measurement device in fluid communication with an outlet of the source vessel, the flow measurement device configured to measure an output flow of the vaporized reactant from the source vessel to the process control chamber.

In another aspect an apparatus for supplying a vaporized reactant to a reaction chamber is provided, the apparatus comprising: a source vessel including a source inlet, a source outlet, and an interior space adapted for receiving a volume of a source material; a process control chamber downstream of and in fluid communication with the source vessel, the process control chamber configured to collect a measured amount of the vaporized reactant from the source vessel prior to delivery of the measured amount of the vaporized reactant to the reaction chamber at a predetermined pressure, the injection gas source configured to supply an injection gas to the process control chamber to enable modification of a pressure within the process control chamber.

In some embodiments the apparatus further comprises a pressure transducer configured to measure the pressure in the process control chamber.

In some embodiments the apparatus further comprises a process control valve disposed between the injection gas source and the process control chamber and configured for controlling the supply of the injection gas to the process control chamber.

In some embodiments the apparatus further comprises a control system configured to communicate with at least the pressure transducer and the process control valve to enable a controlled output of the vaporized reactant at a desired pressure from the process control chamber.

In some embodiments the injection gas source is fluidly coupled to a gas delivery conduit disposed between the source vessel and the process control chamber or is directly coupled to the process control chamber.

In some embodiments the apparatus further comprises a flow measurement device in fluid communication with an outlet of the source vessel, the flow measurement device configured to measure an output flow of the vaporized reactant from the source vessel to the process control chamber.

In another aspect a method of supplying a vaporized reactant to a reaction chamber is provided, the method comprising: vaporizing a solid or liquid reactant contained in a source vessel to form a reactant vapor; transferring the reactant vapor to a process control chamber; collecting the reactant vapor in the process control chamber; supplying an injection gas to the process control chamber from an injection gas source fluidly coupled to the process control chamber to enable modification of a pressure within the process control chamber; and transferring the reactant vapor from the process control chamber to the reaction chamber.

In some embodiments the method further comprises measuring the pressure in the process control chamber with a pressure transducer.

In some embodiments the method further comprises controlling delivery of the reactant vapor to the reaction chamber from the process control chamber with a control system configured to communicate with the process control chamber and the pressure transducer.

In some embodiments transferring the reactant vapor to the process control chamber comprises transferring a measured amount of reactant vapor to the process control chamber.

In some embodiments the measured amount of reactant vapor is determined by measuring a pressure change in the process control chamber using the pressure transducer.

In some embodiments the measure amount of reactant vapor is further determined by a flow measurement device in fluid communication with an outlet of the source vessel, the flow measurement device configured to measure an output flow of the vaporized reactant from the source vessel to the process control chamber.

In some embodiments the method further comprises controlling the pressure within the process control chamber to a value greater than the pressure within the reaction chamber.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates an exemplary reactor system.

FIG. 2 illustrates a reactor system in accordance with one or more embodiments of the disclosure.

FIG. 3 illustrates a method of supplying a vaporized reactant to a reaction chamber in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

The illustrations presented herein are not meant to be actual views of any particular material, apparatus, structure, or device, but are merely representations that are used to describe embodiments of the disclosure.

As used herein, the term “chemical vapor deposition” (CVD) may refer to any process wherein a substrate is exposed to one or more volatile precursors, which react and/or decompose on a substrate surface to produce a desired deposition.

As used herein, the term “atomic layer deposition” (ALD) may refer to a vapor deposition process in which deposition cycles, preferably a plurality of consecutive deposition cycles, are conducted in a reaction chamber. Typically, during each deposition cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the reaction chamber for use in converting the chemisorbed precursor to the desired material on the deposition surface. Typically, this reactant is capable of further reaction with the precursor. Further, purging steps may also be utilized during each cycle to remove excess precursor from the reaction chamber and/or remove excess reactant and/or reaction byproducts from the reaction chamber after conversion of the chemisorbed precursor. Further, the term atomic layer deposition, as used herein, is also meant to include processes designated by related terms such as, chemical vapor atomic layer deposition, atomic layer epitaxy (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As described in greater detail below, various details and embodiments of the disclosure may be utilized in conjunction with processes carried out in reactor systems, e.g., semiconductor fabrication systems, to control an amount of a reactant available for a reaction within a reaction chamber. The “processes” may include such processes as deposition, etching, purging, and the like that may be performed during ALD, CVD, and other processes on a substrate (e.g., a wafer). The “process material” (or “source” or “source material”) may be provided to the reaction chamber from a source vessel where it may in solid or liquid form and may include precursors, reactants, and the like, used during the processes performed during operation of the reactor system.

Apparatus and associated reactor systems having direct control of the amount of chemistry (i.e., the dose of a precursor and/or reactant) transferred to a reaction chamber may provide improved process control and quality of the layer deposited by such apparatus and systems. Accordingly, various embodiments of the present technology disclose apparatus and associated reactor systems comprising a process control chamber positioned between a source vessel and a reaction chamber and configured for providing a controlled transfer of a vaporized reactant to the reaction chamber. Exemplary apparatus and systems can be configured, as described in detail below, to transfer a known amount of chemistry (i.e., the dose of precursor/reactant) to a reaction chamber by controlling the chemistry provided to the reaction chamber as well as controlling the pressure within a process control chamber directly.

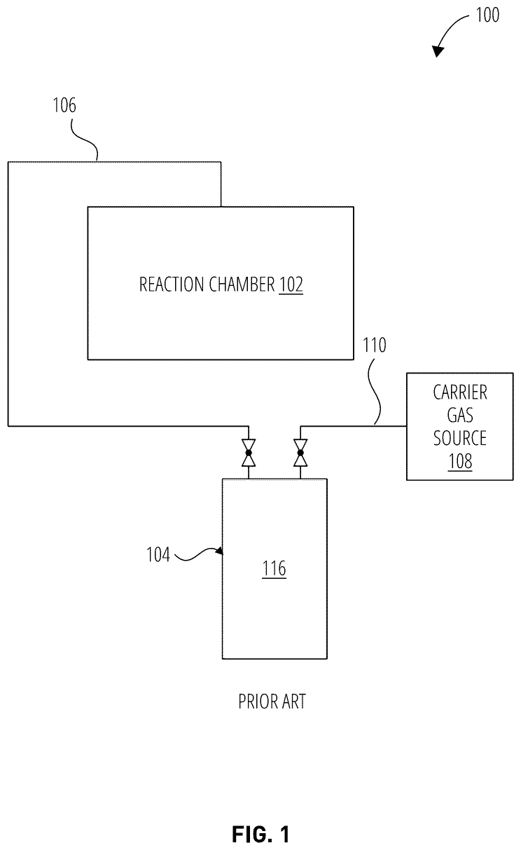

Turning now to the figures, FIG. 1 is a functional block diagram of a reactor system 100 as known in the art. As illustrated in FIG. 1 the reactor system 100 includes a reaction chamber 102 which is supplied with one or more vaporized reactants from a source vessel 104. The reaction chamber 102 is fluidly coupled to the source vessel 104 by a gas conduit 106 configured to transfer the vaporized reactant from the source vessel 104 to the reaction chamber 102. A carrier gas source 108 is positioned upstream of the source vessel 104 and is fluidly coupled to the source vessel 104 via carrier conduit 110. The carrier gas source 108 is configured to supply a carrier gas (e.g., argon or nitrogen) to the source vessel 104. The source vessel 104 includes an interior space 116 containing a heated solid source or liquid source. The source vessel 104 is configured to vaporize the source contained within the interior space 116 and the carrier gas supplied from the carrier gas source 108 is entrained with the vaporized reactant which is then supplied via gas conduit 106 to the reaction chamber 102.

The reactor system 100 of FIG. 1 employs an inert carrier gas such as Ar or N₂ to increase the amount of vaporized reactant supplied to the reaction chamber 102 by continually sweeping or pushing the vaporized reactant disposed in the headspace of the source vessel 104 downstream.

In such a reactor system the use of the carrier gas source upstream of the source vessel may result in the dilution of the vaporized reactant. In such reactor systems the dilution of the vaporized reactant can make monitoring and controlling the concentration of the vaporized reactant supplied to the reaction chamber (i.e., the dosage of the reactant) complex and as result can negatively impact control of processes performed in the reaction chamber 102 of the reactor system 100. In addition, in such a reactor system the amount of vaporized reactant disposed in the headspace of the source vessel 104 can deplete over time as the vaporize reactant is continually transferred to the reaction chamber. The depletion of the vaporized reactant can result in a change over time of the amount of reactant saturated within the carrier gas which can further negatively impact the ability to control the supply of the vaporized reactant to the reaction chamber.

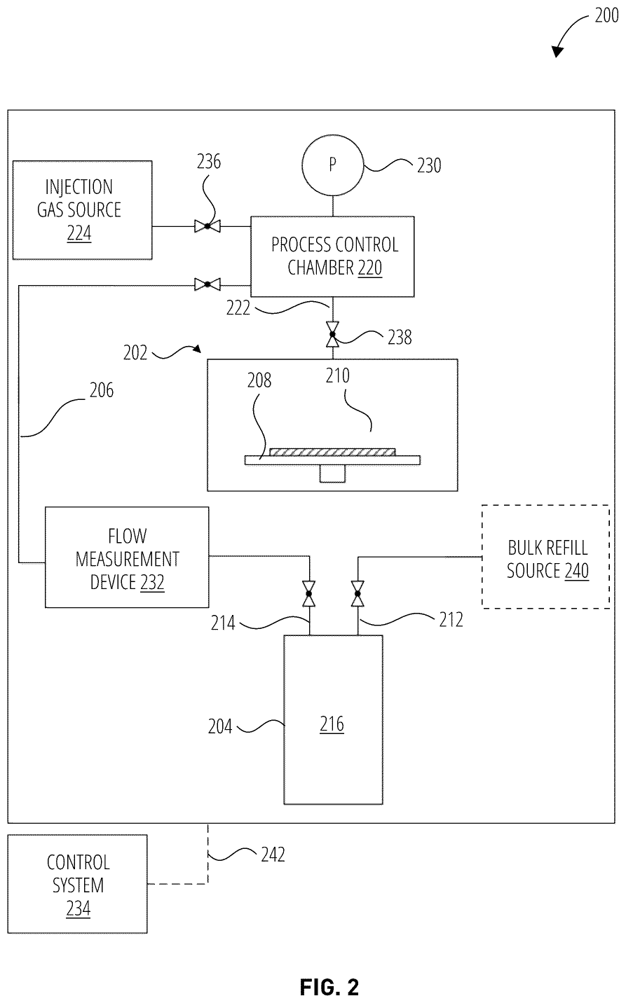

FIG. 2 is a functional block diagram of a reactor system 200 in accordance with various embodiments of the disclosure. The reactor system 200 may comprise an ALD reactor system, a CVD reactor system, or a plasma-enhanced (PE) reactor system, such as for example, a PECVD reactor system or a PECVD reactor system. In accordance with examples of the disclosure, the reactor system 200 may include a reaction chamber 202. In some embodiments the reaction chamber 202 can comprise a component or assembly of a single-wafer ALD reactor or a batch ALD reactor where deposition on multiple substrates takes place at the same time. In some embodiments the reaction chamber 202 may form part of a cluster tool in which a variety of different processes for the fabrication of devices and/or integrated circuit are carried out. In some embodiments a flow-type reactor and associated reaction chamber can be utilized. In some embodiments a high-volume manufacturing-capable single wafer ALD reactor and associated reaction chamber can be used. In other embodiments a batch reactor comprising multiple substrates can be used. For embodiments in which batch ALD reactor are used, the number of substrates can be in the range of 10 to 200, in the range of 50 to 150, or in the range of 100 to 130. Although reactor system 200 is illustrated including a single reaction chamber 202 it should be appreciated that the reactor system 200 may include multiple reaction chambers and/or multiple process modules each including one or more reaction chambers. For example, reactor system 200 may comprise one or more dual chamber modules each including two reaction chambers, and/or one or more quad chamber modules each including four reaction chambers. The reaction chamber 202 may be configured to receive one or more substrates. For example, the reaction chamber 202 may comprise a substrate support 208 upon which substrates (such as substrate 210) may be seated for processing within reaction chamber 202.

In accordance with examples of the disclosure, the reactor system 200 may comprise a source vessel 204. In such examples the source vessel 204 may be configured to supply a vaporized reactant (or vaporized reactants) to the reaction chamber 202. In various embodiments the source vessel comprises a source inlet 212, a source outlet 214, and an interior space 216 adapted for containing and/or receiving a volume of source material. The source vessel can include one or more heating devices to heat the source (solid or liquid) contained within the interior space 116 to form a vaporized reactant.

In accordance with examples of the disclosure, the reactor system 200 may comprise a process control chamber 220. In such examples the process control chamber 220 can meter and/or control the amount of vaporized reactant that is supplied to the reaction chamber 202 along the reactant supply conduit 222. The process control chamber 220 can serve as an intermediate volume in which reactant is collected in vapor form before being delivered to the reaction chamber 202. Controlling the supply of the reactant vapor to the reaction chamber 202 using the process control chamber 220 can beneficially enable more accurate control of the reactant vapor dosage to the reaction chamber 202.

In accordance with examples of the disclosure, the process control chamber 220 can be disposed between the source vessel 204 and the reaction chamber. In such examples, the process control chamber 220 can be positioned downstream of the source vessel. In such examples, the process control chamber 220 can be positioned upstream of the reaction chamber 202. In some embodiments the process control chamber 220 may be positioned downstream of the source vessel 204 and upstream of the reaction chamber 202. In some embodiments the process control chamber 220 can be in fluid communication with the source vessel 204 (via gas conduit 206) and the reaction chamber 202 (via reactant supply conduit 222). In such examples the process control chamber 220 can be configured to collect and/or accumulate the vaporized reactant from the source vessel 204 prior to delivery of the vaporized reactant along the reactant supply conduit 222 to the reaction chamber 202.

In accordance with examples of the disclosure, the reactor system 200 may comprise an injection gas source 224 in fluid communication with the process control chamber 220. In such examples the injection gas source 224 can be configured to supply an injection gas to the process control chamber 220 to enable a modification of the pressure within the process control chamber 220. In one aspect the injection gas source 224 is fluidly coupled directly to the process control chamber 220. In another aspect the injection gas source 224 is fluidly coupled to a gas delivery conduit disposed between the source vessel and the process control chamber. In some embodiments the source vessel 204 does not include a carrier gas source positioned downstream of the source vessel (as illustrated for reactor system 100 of FIG. 1). In such embodiments the vaporized reactant can be transferred to the process control chamber 220 by vapor pressure alone. In such examples the injection gas source 224 and the injection gas supplied there from can be employed as the “push gas” to transfer the vaporized reactant from the process control chamber 220 to the reaction chamber 202.

In accordance with examples of the disclosure, the reactor system 200 can further comprise a pressure transducer 230. In such examples the pressure transducer can be configured to monitor the pressure within the process control chamber 220. In some embodiments the pressure transducer 230 may be integrated directly with the process control chamber 220.

In accordance with examples of the disclosure, the reactor system 200 can further comprise a process control valve 236. In such examples the process control valve 236 can be disposed upstream of the process control chamber 220 and downstream of the injection gas source 224. In the illustrated embodiment the process control valve 236 can be disposed between the injection gas source 224 and the reaction chamber 202. In some embodiments the process control valve 236 may be integrated directly with the process control chamber 220. In some embodiments the process control valve 236 can comprise a binary on/off valve that permits or blocks the flow of injection gas from the injection gas source 224 to the process control chamber 220 for controlling the pressure within the process control chamber 220.

In accordance with examples of the disclosure, the reactor system 200 may further comprise a control system 234. In such examples the control system 234 can be configured to communicate with at least the process control valve 236 and the pressure transducer 230. In some embodiments the control system 234 can determine the amount (e.g., concentration/dose) of the vaporized reactant provided to the process control chamber 220 by monitoring a change in pressure within the process control chamber 220 (e.g., employing the pressure transducer 230) as the vaporized reactant is transferred to the process control chamber 220 from the source vessel 204 via gas conduit 206. In such embodiments once a predetermined measured amount of the vaporized reactant has been transferred to the process control chamber 220, the control system 234 may communicate with the process control valve 236 to open the process control valve 236 thereby allow the flow of injection gas from the injection gas source 224 to the process control chamber 220. In such embodiments the pressure within the process control chamber 220 can be set (i.e., charged) to a desired level (using the injection gas flow) prior to opening the reactant supply valve 238 and transferring a predetermined measured amount of vaporized reactant at a desired pressure from the process control chamber 220 to the reaction chamber 202. Therefore, in some embodiments the process control chamber is configured to collect a measured amount of the vaporized reactant from the source vessel prior to delivery of the measured amount of the vaporized reactant to the reaction chamber at a predetermined pressure.

In accordance with examples of the disclosure, the control system 234 can include a feedback circuit that can electrically connect and communicate via a control line 242 (e.g., an electrical or optical line or alternatively via wireless communication) with the pressure transducer 230 and the process control valve 236. In addition, the control system 234 can control the operation of various components of the reactor system 200. In some embodiments the control system 234 can comprise processing electronics configured to control the operation of one or more of the valves, such as the process control valve 236 and the reactant supply valve 238, for example. In addition, the control system 234 can be configured to communicate with and control the source vessel 204 and the reaction chamber 202 (and the various components therein). Although illustrated as a single structure in FIG. 2, it should be appreciated that the control system 234 can include a plurality of controllers or sub-systems that have processors, memory devices, and other electronic components that control the operation of the various components of the reactor system 200. As used herein, the term “control system” includes any combination of individual controller devices and processing electronics that may be integrated with or connected to other devices (such as valves, sensors, etc.). Thus, in some embodiments the control system 234 can include a centralized controller that controls the operation of multiple (or all) system components. In some embodiments, the control system 234 can comprise a plurality of distributed controllers that control the operation of one or more system components. Control sequences can be hardwired or programmed into the control system 234.

In some embodiments the injection gas source 224 is configured to increase the pressure within the process control chamber 220 above the pressure within the reaction chamber 202. In some embodiments the pressure in the process control chamber may be increased beyond that in the reaction chamber 202 to ensure a sufficient amount of vaporized reactant is supplied to the reaction chamber to enable reactant saturation on the substrate 210 disposed within the reaction chamber 202. For example, a pressurized dose of vaporized reactant may be beneficial when the substrate 210 disposed within the reaction chamber 202 comprises high aspect ratio features. In other examples, a pressurized dose of vaporized reactant may be beneficial due to conductance losses in various components (not shown) of the reaction chamber 202, such as, for example, a showerhead, a valve manifold, or additional gas lines/valves, and the like.

In accordance with examples of the disclosure, the reactor system 200 may further comprise a flow measurement device 232 in fluid communication with the source outlet 214 of the source vessel 204. In such examples the flow measurement device 232 can be configured to measure an output flow of the vaporized reactant supplied from the source vessel 204 to the process control chamber 220. In some embodiments the total amount of vaporized reactant supplied to the process control chamber 220 can be monitored by the flow measurement device 232. In such examples the flow measurement device 232 may comprise an in-line mass flow monitor (MFM), or other sensor(s) and devices with the capability to monitor the mass flow of the vaporized reactant. In such examples the control system 234 can be configured to communicate with at least the process control valve 236, the pressure transducer 230, and the flow measurement device 232. In some embodiments the control system 234 can determine the amount of the vaporized reactant provided to the process control chamber 220 by monitoring the flow measurement device 232 as the vaporized reactant is transferred to the process control chamber 220 from the source vessel 204. For example, the flow measurement device 232 may be employed in conjunction with the pressure transducer 230 to determine the amount of vaporized reactant transferred to the process control chamber 220. In such examples the pressure within the process control chamber 220 can be set (i.e., charged) to a desired level (using the injection gas flow) prior to opening the reactant supply valve 238 and transferring a predetermined measured amount of vaporized reactant (as determined by the flow measurement device 232 and/or the pressure transducer 230) at a desired pressure from the process control chamber 220 to the reaction chamber 202. In some embodiments an additional flow measurement device (not shown) can be place between the injection gas source 224 and the process control chamber 220 to monitor and control the mass flow of the injection gas from the injection gas source to the process control chamber.

As explained above, it can be challenging to control the amount of the vaporized reactant transferred to the reaction chamber 202. Beneficially, the reactor system 200 (of FIG. 2) can include feedback control of the pressure in the process control chamber 220 to control the pressure of the measured amount of vaporized reactant provided to the reaction chamber 202 from the process control chamber 220. For example, the process control valve 236 can be activated by the control system 234 to close and open based on the measured pressure (e.g., from the pressure transducer 230) in the process control chamber 220. In another aspect, the reactor system 200 (of FIG. 2) can include feedback control of the flow of vaporized reactant to the process control chamber 220 employing the flow measurement device 232 to control the amount of vaporized reactant provided to the reaction chamber 202 from the process control chamber 220. For example, the process control valve 236 can be activated by the control system 234 to close and open based on the amount of vaporized reactant transferred to the process control chamber 220 as measured by the flow measurement device 232 and the pressure (e.g., from the pressure transducer 230) in the process control chamber 220.

In accordance with examples of the disclosure, the reactor system 200 can also optionally include a bulk refill source configured to resupply source material (i.e., solid, or liquid sources) to the source vessel 204. In some embodiments the bulk refill source 240 may also include a carrier gas source configured for supplying a carrier gas to the source vessel. In alternative embodiments the reactor system 200 does not include a carrier gas source configured for supplying a carrier gas to the source vessel.

The various embodiments of the disclosure also provide apparatus for supplying a vaporized reactant to a reaction chamber. In accordance with examples of the disclosure, the apparatus can comprise a source vessel including a source inlet, a source outlet, and an interior space adapted for receiving a volume of a source material. In accordance with examples of the disclosure, the apparatus can further comprise a process control chamber downstream of and in fluid communication with the source vessel. In such examples the process control chamber can be configured to collect and transfer the vaporized reactant to a reaction chamber downstream of the process control chamber. In accordance with examples of the disclosure, the apparatus can further comprise an injection gas source in fluid communication with the process control chamber. In such examples the injection gas source can be configured to supply an injection gas to the process control chamber to enable modification of a pressure within the process control chamber. In some embodiments the injection gas source can be fluidly coupled to a gas delivery conduit disposed between the source vessel and the process control chamber. In some embodiments the injection gas source can be fluidly coupled directly to the process control chamber.

In accordance with examples of the disclosure, the apparatus can further comprise a pressure transducer configured to measure the pressure in the process control chamber.

In accordance with examples of the disclosure, the apparatus can further comprise a process control valve disposed between the injection gas source and the process control chamber. In such examples the process control valve can be configured for controlling the supply of the injection gas to the process control chamber.

In accordance with examples of the disclosure, the apparatus can further comprise a control system configured to communicate with at least the pressure transducer and the process control valve to enable a controlled output of the vaporized reactant at a desired pressure from the process control chamber.

In accordance with examples of the disclosure, the apparatus can further comprise a flow measurement device in fluid communication with an outlet of the source vessel. In such examples the flow measurement device can be configured to measure an output flow of the vaporized reactant from the source vessel to the process control chamber.

The various embodiments of the disclosure also provide methods for supplying a vaporized reactant to a reaction chamber.

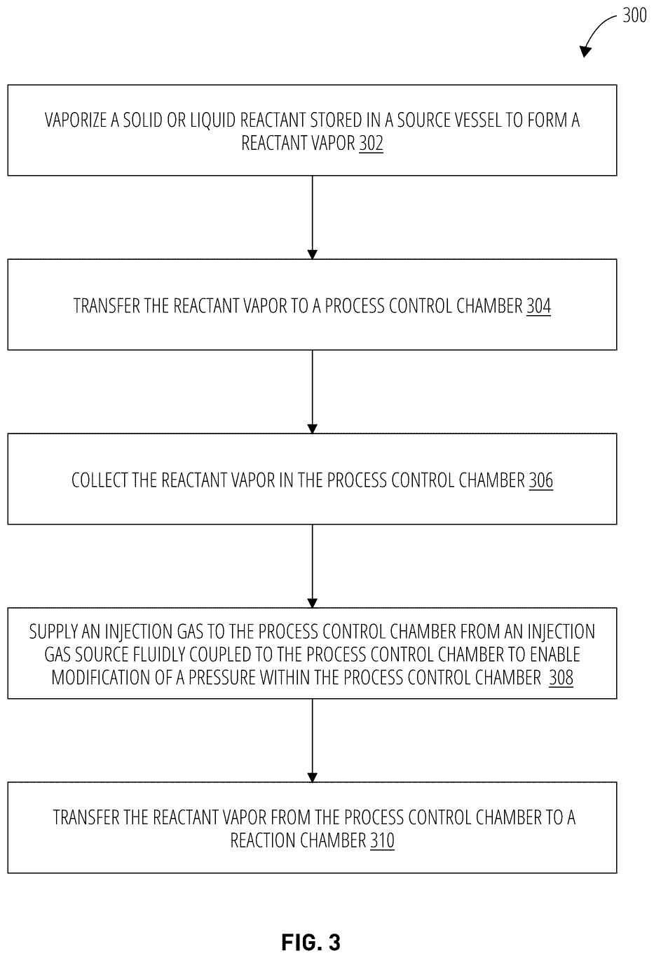

Turning again to the figures, FIG. 3 illustrates exemplary method 300 for supplying a vaporized reactant to a reaction chamber. In such methods the reaction chamber may comprise the reaction chamber 202 of the reactor system 200, for example.

In accordance with examples of the disclosure, the method 300 may comprise vaporizing a solid or liquid reactant contained in a source vessel to form a reactant vapor (step 302).

In accordance with examples of the disclosure, method 300 may further comprise transferring the reactant vapor to a process control chamber (step 304). In such examples the method 300 may further comprise transferring a measured amount of reactant vapor to the process control chamber. In some embodiments the measured amount of reactant vapor is determined by measuring a pressure change in the process control chamber using a pressure transducer. In some embodiments the measured amount of reactant vapor is further determined by a flow measurement device in fluid communication with an outlet of the source vessel. In such embodiments the flow measurement device can be configured to measure an output flow of the vaporized reactant from the source vessel to the process control chamber.

In accordance with examples of the disclosure, method 300 may comprise collecting the reactant vapor in the process control chamber (step 306).

In accordance with examples of the disclosure, method 300 may comprise supplying an injection gas to the process control chamber from an injection gas source fluidly coupled to the process control chamber to enable modification of a pressure within the process control chamber (step 308). In some embodiments controlling the pressure within the process control chamber may comprise controlling the pressure to a value greater than the pressure within the reaction chamber.

In accordance with examples of the disclosure, method 300 may comprise transferring the reactant vapor from the process control chamber to a reaction chamber (step 310). In some embodiments a measured amount of reactant vapor is transferred to the reaction chamber at a known pressure.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A reactor system, comprising:
a reaction chamber configured to receive one or more substrates;
a source vessel configured to supply a vaporized reactant to the reaction chamber, the source vessel comprising a source inlet, a source outlet, and an interior space adapted for receiving a volume of a source material;
a process control chamber disposed between the source vessel and the reaction chamber, the process control chamber being in fluid communication with the source vessel and the reaction chamber and configured to:
collect a measured amount of the vaporized reactant from the source vessel; and
deliver the measured amount of the vaporized reactant to the reaction chamber at a predetermined pressure; and
an injection gas source in fluid communication with the process control chamber, the injection gas source configured to supply an injection gas to the process control chamber to enable modification of a pressure within the process control chamber.

2. The reactor system of claim 1, further comprising a pressure transducer configured to monitor the pressure in the process control chamber.

3. The reactor system of claim 2, further comprising a process control valve disposed between the injection gas source and the process control chamber and configured for controlling the supply of the injection gas to the process control chamber.

4. The reactor system of claim 3, further comprising a control system configured to communicate with at least the pressure transducer and the process control valve to enable a controlled delivery of the vaporized reactant at the predetermined pressure desired pressure to the reaction chamber from the process control chamber.

5. The reactor system of claim 4, wherein the injection gas source is configured to increase a pressure within the process control chamber above a pressure within the reaction chamber.

6. The reactor system of claim 5, where the injection gas source is fluidly coupled directly to the process control chamber.

7. The reactor system of claim 1, further comprising a flow measurement device in fluid communication with an outlet of the source vessel, the flow measurement device configured to measure an output flow of the vaporized reactant from the source vessel to the process control chamber.

8. An apparatus for supplying a vaporized reactant to a reaction chamber, the apparatus comprising:
a source vessel comprising a source inlet, a source outlet, and an interior space adapted for receiving a volume of a source material;
a process control chamber downstream of and in fluid communication with the source vessel, the process control chamber configured to:
collect a measured amount of the vaporized reactant from the source vessel; and
deliver the measured amount of the vaporized reactant to the reaction chamber at a predetermined pressure; and
an injection gas source in direct fluid communication with the process control chamber, the injection gas source configured to supply an injection gas to the process control chamber to enable modification of a pressure within the process control chamber; and
a flow measurement device in fluid communication with the source outlet of the source vessel, the flow measurement device configured to measure an output flow of the vaporized reactant from the source vessel to the process control chamber, wherein the flow measurement device is positioned downstream of the source vessel and upstream of the process control chamber.

9. The apparatus of claim 8, further comprising a pressure transducer configured to measure the pressure in the process control chamber.

10. The apparatus of claim 9, further comprising a process control valve disposed between the injection gas source and the process control chamber and configured for controlling the supply of the injection gas to the process control chamber.

11. The apparatus of claim 10, further comprising a control system configured to communicate with at least the pressure transducer, the flow measurement device, and the process control valve to enable a controlled output of the vaporized reactant at the predetermined pressure from the process control chamber to the reaction chamber based on the measured pressure in the process control chamber.

12. The apparatus of claim 11, where the injection gas source is fluidly coupled to a gas delivery conduit disposed between the source vessel and the process control chamber or is directly coupled to the process control chamber.

13. The apparatus of claim 12, wherein the control system is configured to open the process control valve and supply injection gas to the process control chamber based the measured amount of the vaporized reactant supplied from the source vessel as determined by the flow measurement device.

14. A method of supplying a vaporized reactant to a reaction chamber, the method comprising:
vaporizing a solid or liquid reactant contained in a source vessel to form a reactant vapor;
transferring the reactant vapor to a process control chamber;
collecting the reactant vapor in the process control chamber;
supplying an injection gas to the process control chamber from an injection gas source fluidly coupled to the process control chamber to enable modification of a pressure within the process control chamber; and
transferring the reactant vapor from the process control chamber to the reaction chamber.

15. The method of claim 14, further comprising measuring the pressure in the process control chamber with a pressure transducer.

16. The method of claim 15, further comprising controlling delivery of the reactant vapor to the reaction chamber from the process control chamber with a control system configured to communicate with the process control chamber and the pressure transducer.

17. The method of claim 16, wherein transferring the reactant vapor to the process control chamber comprises transferring a measured amount of reactant vapor to the process control chamber.

18. The method of claim 17, wherein the measured amount of reactant vapor is determined by measuring a pressure change in the process control chamber using the pressure transducer.

19. The method of claim 18, wherein the measured amount of reactant vapor is further determined by a flow measurement device in fluid communication with an outlet of the source vessel, the flow measurement device configured to measure an output flow of the vaporized reactant from the source vessel to the process control chamber.

20. The method of claim 15, further comprising controlling the pressure within the process control chamber to a value greater than the pressure within the reaction chamber.
